(19) United States
(12) Patent Application Publication
(10) Pub. No.: US 2026/0011306 A1
(43) Pub. Date: Jan. 8, 2026

(54) Reducing Content Dependent Anode Reset Noise During Touch Sensing Operations in a Display

(71) Applicant: Apple Inc., Cupertino, CA (US)

(72) Inventors: Shinya Ono, Santa Clara, CA (US); Chin-Wei Lin, San Jose, CA (US); Qing Li, Saratoga, CA (US); Ting-Kuo Chang, San Jose, CA (US); Zino Lee, San Diego, CA (US); Dong-Gwang Ha, Santa Clara, CA (US); Po-Hsuan Chang, San Diego, CA (US); Hassan Edrees, Santa Clara, CA (US); Shrestha Bansal, Cupertino, CA (US); Warren S. Rieutort-Louis, Cupertino, CA (US); Woo-Suhl Cho, San Jose, CA (US); Hao-Lin Chiu, Los Gatos, CA (US); Szu-Hsien Lee, Los Gatos, CA (US)

(21) Appl. No.: 19/205,711

(22) Filed: May 12, 2025

Related U.S. Application Data
(60) Provisional application No. 63/667,051, filed on Jul. 2, 2024.

(51) Int. Cl. G09G 3/3233; G06F 3/041; H10K 59/121; H10K 59/122; H10K 59/126; H10K 59/131; H10K 59/40; H10K 59/80

(52) U.S. Cl. CPC G09G 3/3233; H10K 59/1213; H10K 59/122; H10K 59/131; H10K 59/40; H10K 59/8052; H10K 59/873; G06F 3/0418; G09G 2300/0819; G09G 2300/0852; G09G 2300/0861; G09G 2310/08; G09G 2354/00; H10K 59/126

(57) ABSTRACT

An electronic device may include display and touch circuitry. The circuitry may include an array of pixels. Each pixel in the array may include at least a light-emitting diode, a drive transistor coupled in series with the light-emitting diode, a storage capacitor coupled to a gate terminal of the drive transistor, and an anode reset transistor configured to reset an anode of the light-emitting diode and coupled to an anode reset voltage line. The light-emitting diode may have a cathode that is capacitively coupled to one or more touch sensor electrodes. The anode reset transistor may be activated while the touch sensor electrodes are performing touch sensing operations during a vertical blanking period. The cathode can be formed from a cathode layer driven to a ground voltage and disconnected from one or more electrically floating cathode layer portions elevated relative to the cathode layer by floating cathode support structures.

This application claims the benefit of U.S. Provisional Patent Application No. 63/667,051, filed Jul. 2, 2024, which is hereby incorporated by reference herein in its entirety.

### FIELD

This relates generally to electronic devices, and, more particularly, to electronic devices with displays.

### BACKGROUND

Electronic devices often have displays. Touch sensors are sometimes incorporated into displays. If care is not taken, noise from a display can interfere with the touch sensor functionality.

### SUMMARY

An aspect of the disclosure provides circuitry that includes a light-emitting diode, a drive transistor coupled in series with the light-emitting diode, a storage capacitor coupled to a gate terminal of the drive transistor, and an anode reset transistor configured to reset an anode of the light-emitting diode and coupled to an anode reset voltage line. The light-emitting diode can have a cathode that is electrically coupled to one or more touch sensor electrodes. The anode reset transistor can be activated while the touch sensor electrodes are performing touch sensing operations. The circuitry can optionally further include a first emission transistor coupled between a power supply line and the drive transistor, a second emission transistor coupled between the drive transistor and the light-emitting diode, an additional capacitor coupled having a first terminal coupled to the power supply line and having a second terminal coupled to a node between the drive transistor and the second emission transistor, a data loading transistor coupled between a data line and the gate terminal of the drive transistor, and a gate-voltage-setting transistor coupled between a reference voltage line and the gate terminal of the drive transistor.

An aspect of the disclosure provides circuitry that includes a plurality of display pixel regions, pixel definition structures formed along a periphery of the plurality of display pixel regions, a cathode layer overlapping with the plurality of display pixel regions, cathode layer portions disconnected from the cathode layer and formed directly over portions of the pixel definition structures, and one or more touch sensor electrodes disposed over the cathode layer portions. The cathode layer can be electrically coupled to a ground power supply voltage, and the cathode layer portions can be electrically floating. The circuitry can further include floating cathode support structures formed between the pixel definition structures and the cathode layer portions.

An aspect of the disclosure provides a method of operating a touch screen display, the method including: outputting a first scan pulse to a first row of display pixels, where the first scan pulse is configured to activate a plurality of anode reset transistors in the first row of display pixels; after outputting the first scan pulse, outputting a second scan pulse to a second row of display pixels, wherein the second scan pulse is configured to activate a plurality of anode reset transistors in the second row of display pixels; and performing touch sensing operations while outputting the first and second scan pulses. The first scan pulse and the second scan pulse can be offset by at least one row time of the touch screen display. The first and second can pulses can each have a pulse width that is greater than 50% of an emission off period. The various scan pulses can be generated using one or more gate drivers disposed along one or more edges of the touch screen display.

### BRIEF DESCRIPTION OF THE DRAWINGS

FIG. 1 is a schematic diagram of an illustrative electronic device in accordance with some embodiments.

FIG. 2 is a diagram of an illustrative display having an array of organic light-emitting diode (OLED) display pixels in accordance with some embodiments.

FIG. 3 is a side view of a touch screen display in accordance with some embodiments.

FIG. 4 is a flowchart of illustrative steps for operating a touch screen display in accordance with some embodiments.

FIG. 5A is a circuit diagram of an illustrative display pixel being configured to reduce cathode rippling in accordance with some embodiments.

FIG. 5B is a timing diagram showing illustrative signals for operating the display pixel shown in FIG. 5A in accordance with some embodiments.

FIG. 6A is a circuit diagram of an illustrative display pixel having at least three transistors in an anode reset path in accordance with some embodiments.

FIG. 6B is a timing diagram showing illustrative signals for operating the display pixel shown in FIG. 6A in accordance with some embodiments.

FIG. 7A is a circuit diagram of an illustrative display pixel having two separate anode reset paths in accordance with some embodiments.

FIG. 7B is a timing diagram showing illustrative signals for operating the display pixel shown in FIG. 7A in accordance with some embodiments.

FIG. 8 is a circuit diagram of an illustrative display pixel having a separate anode reset path with at least two series transistors in accordance with some embodiments.

FIG. 9 is a cross-sectional side view of a continuous cathode layer formed over a pixel definition structure in some portions of a display in accordance with some embodiments.

FIG. 10 is a cross-sectional side view of a discontinuous cathode layer formed over a pixel definition structure in other portions of a display in accordance with some embodiments.

FIG. 11 is a top (layout) view of a display pixel having at least three subpixels in accordance with some embodiments.

FIG. 12 is a top (layout) view of a cathode layer in the display pixel of FIG. 11 in accordance with some embodiments.

FIG. 13A is a diagram of a per-row head-to-head anode reset driving scheme in accordance with some embodiments.

FIG. 13B is a timing diagram for operating the driving scheme of FIG. 13A for reducing cathode rippling in accordance with some embodiments.

FIG. 14A is a diagram of a per-row single-ended, interlaced anode reset driving scheme in accordance with some embodiments.

FIG. 14B is a timing diagram for operating the driving scheme of FIG. 14A for reducing cathode rippling in accordance with some embodiments.

FIG. 15A is a diagram of a per-row single-ended anode reset driving scheme with color split in accordance with some embodiments.

FIG. 15B is a timing diagram for operating the driving scheme of FIG. 15A for reducing cathode rippling in accordance with some embodiments.

### DETAILED DESCRIPTION

Electronic devices may be provided with displays. Displays may be used for displaying images for users. Displays may be formed from arrays of light-emitting diode pixels or other pixels. For example, a device may have an organic light-emitting diode (OLED) display. The electronic devices may have sensors such touch sensors. This provides the display with touch screen capabilities.

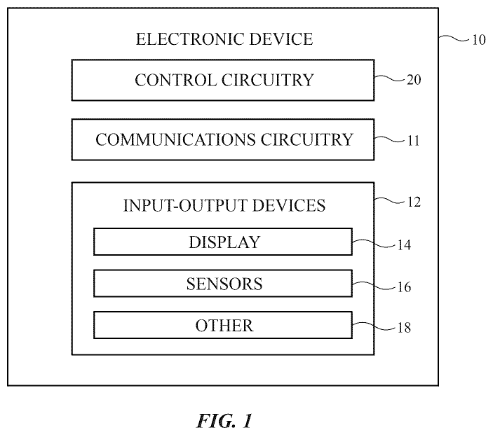

A schematic diagram of an illustrative electronic device having a display is shown in FIG. 1. Device 10 may be a cellular telephone, tablet computer, laptop computer, wristwatch device or other wearable device, a television, a stand-alone computer display or other monitor, a computer display with an embedded computer (e.g., a desktop computer), a system embedded in a vehicle, kiosk, or other embedded electronic device, a media player, or other electronic equipment. Configurations in which device 10 is a wristwatch, cellular telephone, tablet computer, or other portable electronic device may sometimes be described herein as an example. This is illustrative. Device 10 may, in general, be any suitable electronic device with a display.

Device 10 may include control circuitry 20. Control circuitry 20 may include storage and processing circuitry for supporting the operation of device 10. The storage and processing circuitry may include storage such as nonvolatile memory (e.g., flash memory or other electrically-programmable-read-only memory configured to form a solid state drive), volatile memory (e.g., static or dynamic random-access-memory), etc. Processing circuitry in control circuitry 20 may be used to gather input from sensors and other input devices and may be used to control output devices. The processing circuitry may be based on one or more microprocessors, application processors, microcontrollers, digital signal processors, baseband processors and other wireless communications circuits, power management units, audio chips, application specific integrated circuits, etc. The processing circuitry of circuitry 20 is sometimes referred to as an application processor or a system processor. During operation, control circuitry 20 may use a display and other output devices in providing a user with visual output and other output.

To support communications between device 10 and external equipment, control circuitry 20 may communicate using communications circuitry 11. Circuitry 11 may include antennas, radio-frequency transceiver circuitry (wireless transceiver circuitry), and other wireless communications circuitry and/or wired communications circuitry. Circuitry 11, which may sometimes be referred to as control circuitry and/or control and communications circuitry, may support bidirectional wireless communications between device 10 and external equipment over a wireless link (e.g., circuitry 11 may include radio-frequency transceiver circuitry such as wireless local area network transceiver circuitry configured to support communications over a wireless local area network link, near-field communications transceiver circuitry configured to support communications over a near-field communications link, cellular telephone transceiver circuitry configured to support communications over a cellular telephone link, or transceiver circuitry configured to support communications over any other suitable wired or wireless communications link). Wireless communications may, for example, be supported over a Bluetooth® link, a WiFi® link, a wireless link operating at a frequency between 6 GHz and 300 GHz, a 60 GHz link, or other millimeter wave link, cellular telephone link, wireless local area network link, personal area network communications link, or other wireless communications link. Device 10 may, if desired, include power circuits for transmitting and/or receiving wired and/or wireless power and may include batteries or other energy storage devices. For example, device 10 may include a coil and rectifier to receive wireless power that is provided to circuitry in device 10.

Device 10 may include input-output devices such as devices 12. Input-output devices 12 may be used in gathering user input, in gathering information on the environment surrounding the user, and/or in providing a user with output. Devices 12 may include one or more displays such as display 14. Display 14 may be an organic light-emitting diode display, a liquid crystal display, an electrophoretic display, an electrowetting display, a plasma display, a microelectromechanical systems display, a display having a pixel array formed from crystalline semiconductor light-emitting diode dies (sometimes referred to as microLEDs), and/or other display. Configurations in which display 14 is an organic light-emitting diode display are sometimes described herein as an example.

Sensors 16 in input-output devices 12 may include force sensors (e.g., strain gauges, capacitive force sensors, resistive force sensors, etc.), audio sensors such as microphones, touch and/or proximity sensors such as capacitive sensors (e.g., a two-dimensional capacitive touch sensor integrated into display 14, a two-dimensional capacitive touch sensor overlapping display 14, and/or a touch sensor that forms a button, trackpad, or other input device not associated with a display), and other sensors. Display 14 with overlapping touch sensor circuitry that provide touch sensing functionality may sometimes be referred to as a touch screen display. If desired, sensors 16 may include optical sensors such as optical sensors that emit and detect light, ultrasonic sensors, optical touch sensors, optical proximity sensors, and/or other touch sensors and/or proximity sensors, monochromatic and color ambient light sensors, image sensors, fingerprint sensors, temperature sensors, sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices that capture three-dimensional images), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 16 and/or other input-output devices to gather user input. For example, buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.

If desired, electronic device 10 may include additional components (see, e.g., other devices 18 in input-output devices 12). The additional components may include haptic output devices, audio output devices such as speakers, light-emitting diodes for status indicators, light sources such as light-emitting diodes that illuminate portions of a housing and/or display structure, other optical output devices, and/or other circuitry for gathering input and/or providing output. Device 10 may also include a battery or other energy storage device, connector ports for supporting wired communication with ancillary equipment and for receiving wired power, and other circuitry.

Display 14 may have a rectangular shape (i.e., display 14 may have a rectangular footprint and a rectangular peripheral edge that runs around the rectangular footprint) or may have other suitable shapes. Display 14 may be planar or may have a curved profile.

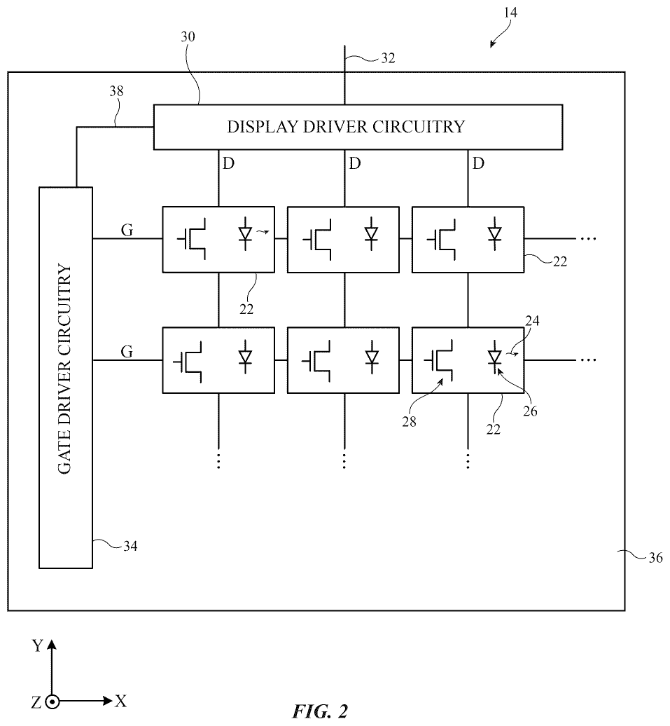

A top view of a portion of display 14 is shown in FIG. 2. As shown in FIG. 2, display 14 may have an array of pixels 22 formed on a substrate 36. Pixels 22 are sometimes referred to as display pixels. Substrate 36 may be formed from glass, metal, plastic, ceramic, porcelain, or other substrate materials. Pixels 22 may receive data signals over signal paths such as data lines D (sometimes referred to as data signal lines, column lines, etc.) and may receive one or more control signals over control signal paths such as horizontal control lines G (sometimes referred to as gate lines, scan lines, emission lines, row lines, etc.). There may be any suitable number of rows and columns of pixels 22 in display 14 (e.g., tens or more, hundreds or more, or thousands or more).

Each display pixel 22 may have a light-emitting diode 26 that emits light 24 under the control of a pixel control circuit formed from thin-film transistor circuitry such as thin-film transistors 28 and thin-film capacitors). Thin-film transistors 28 may be polysilicon thin-film transistors, semiconducting oxide thin-film transistors such as indium zinc gallium oxide transistors, or thin-film transistors formed from other semiconductors. Pixels 22 may contain light-emitting diodes of different colors (e.g., red, green, and blue) to provide display 14 with the ability to display color images.

Display driver circuitry 30 may be used to control the operation of pixels 22. The display driver circuitry 30 may be formed from integrated circuits, thin-film transistor circuits, or other suitable electronic circuitry. Display driver circuitry 30 of FIG. 2 may contain communications circuitry for communicating with system control circuitry such as control circuitry 16 of FIG. 1 over path 32. Path 32 may be formed from traces on a flexible printed circuit or other cable. During operation, the control circuitry (e.g., control circuitry 16 of FIG. 1) may supply circuitry 30 with information on images to be displayed on display 14.

To display the images on display pixels 22, display driver circuitry 30 may supply image data to data lines D (e.g., data lines that run down the columns of pixels 22) while issuing clock signals and other control signals to supporting display driver circuitry such as gate driver circuitry 34 over path 38. If desired, display driver circuitry 30 may also supply clock signals and other control signals to gate driver circuitry 34 on an opposing edge of display 14 (e.g., the gate driver circuitry may be formed on more than one side of the display pixel array).

Gate driver circuitry 34 (sometimes referred to as horizontal line control circuitry or row driver circuitry) may be implemented as part of an integrated circuit and/or may be implemented using thin-film transistor circuitry. Horizontal/row control lines G in display 14 may carry gate line signals (scan line control signals), emission enable control signals, and/or other horizontal control signals for controlling the pixels of each row. There may be any suitable number of horizontal control signals per row of pixels 22 (e.g., one or more row control lines, two or more row control lines, three or more row control lines, four or more row control lines, five or more row control lines, etc.).

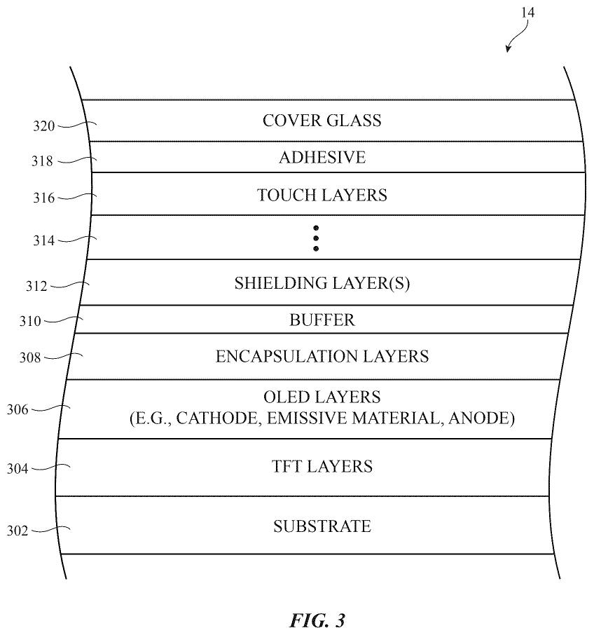

FIG. 3 is a cross-sectional side view of a touch screen display 14 (i.e., a display with overlapping touch sensor circuitry). As shown in FIG. 3, display 14 may include a substrate such as substrate 302. Substrate 302 may be formed from glass, metal, plastic, ceramic, sapphire, or other suitable substrate materials. As examples, substrate 302 may be an organic substrate formed from polyimide (PI), polyethylene terephthalate (PET), or polyethylene naphthalate (PEN). The surface of substrate 302 may optionally be covered with one or more buffer layers (e.g., inorganic buffer layers such as layers of silicon oxide, silicon nitride, etc.).

Thin-film transistor (TFT) layers 304 may be formed over substrate 302. The TFT layers 304 may include thin-film transistor circuitry such as thin-film transistors (e.g., silicon transistors, semiconducting oxide transistors, etc.), thin-film capacitors, associated routing circuitry, and other thin-film structures formed within multiple metal routing layers and dielectric layers. Organic light-emitting diode (OLED) layers 306 may be formed over the TFT layers 304. The OLED layers 306 may include a cathode layer, an anode layer, and emissive material interposed between the cathode and anode layers. The cathode layer is typically formed above the anode layer. The cathode layer may be biased to a ground power supply voltage ELVSS. Ground power supply voltage ELVSS may be 0 V, −2 V, −4, −6V, less than −8 V, −10V, −12V, or any suitable ground or negative power supply voltage level. If desired, the cathode layer may be formed under the anode layer.

Circuitry formed in the TFT layers 304 and the OLED layers 306 may be protected by encapsulation layers 308. As an example, encapsulation layers 308 may include a first inorganic encapsulation layer, an organic encapsulation layer formed on the first inorganic encapsulation layer, and a second inorganic encapsulation layer formed on the organic encapsulation layer. Encapsulation layers 308 formed in this way can help prevent moisture and other potential contaminants from damaging the conductive circuitry covered by layers 308. This is merely illustrative. Encapsulation layers 308 may include any number of inorganic and/or organic barrier layers formed over the OLED layers 306.

One or more buffer layers such as layer 310 may be formed on encapsulation layers 308. Buffer layer 310 may be formed from silicon oxide, silicon nitride, or other suitable buffering materials.

One or more touch layers 316 that implement the touch sensor functions of touch screen display 14 may be formed over the display layers. For example, touch (sensor) layers 316 may include touch sensor circuitry such as horizontal touch sensor electrodes and vertical touch sensor electrodes collectively forming an array of capacitive touch sensor electrodes. A cover glass layer 320 may be formed over the touch sensor layers 316 using adhesive 318 (e.g., optically clear adhesive material). Cover glass 320 may serve as an outer protective layer for display 14.

In certain applications, noise from the display circuitry (e.g., the circuitry in layers 304 and 306) can leak or be inadvertently coupled to the touch sensor circuitry (e.g., the circuitry in layers 316). For example, power supply noise on the upper cathode layer can sometimes be inadvertently coupled to the touch sensor circuitry. Such display noise can potentially degrade the accuracy and performance of the touch sensor circuitry. Display noise may be particularly problematic at higher refresh rates (e.g., refresh rates of greater than 60 Hz, greater than 80 Hz, greater than 100 Hz, 120 Hz or greater, etc.). In accordance with some embodiments, one or more shielding layers such as shielding layer(s) 312 may be interposed between the display circuitry and the touch sensor circuitry. As shown in the stackup of FIG. 3, shielding layer 312 may be formed on buffer layer 310 above the display encapsulation layers 308. Buffer layer 310 may sometimes be considered to be part of shielding layers 312. Shielding layer 312 may be implemented as a conductive mesh structure, a transparent conductive film, a conductive mesh structure overlapped by a transparent conductive film, or other suitable electrical shielding configurations. The presence of shielding layer 312 reduces the capacitive coupling between the display and touch sensor circuities and thus helps to mitigate the effect of display noise on the touch sensor structures. The shielding layer 312 can be actively driven using noise canceling signals or passively driven using a direct current (DC) power supply voltage source. Shielding layer 312 may therefore sometimes be referred to as a noise shielding layer. Shielding layer 312 is optional.

If desired, one or more layers 314 may be interposed between shielding layer 312 and touch sensor layers 316. Layers 314 may include one or more polarizer films, optically clear adhesive films, and other suitable layers in a touch screen display. In general, other layers (not shown) may also be included in the stackup of FIG. 3.

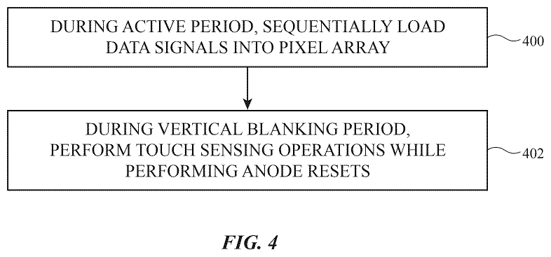

FIG. 4 is a flowchart of illustrative steps for operating a touch screen display of device 10 in accordance with some embodiments. During the operations of block 400, display driver circuitry 30 and gate driver circuitry 34 may sequentially load data signals into the array of pixels during an active period. During the active period, the display pixels can be refreshed with newly loaded data signals while also performing anode reset operations (e.g., for resetting an anode terminal of light-emitting diode 26 in each pixel 22). In other words, the active period includes a plurality of data refresh periods. During the active period, the diodes 26 in display pixels 22 can also be configured to emit light during a period sometimes referred to as an “active” emission or emission “on” period.

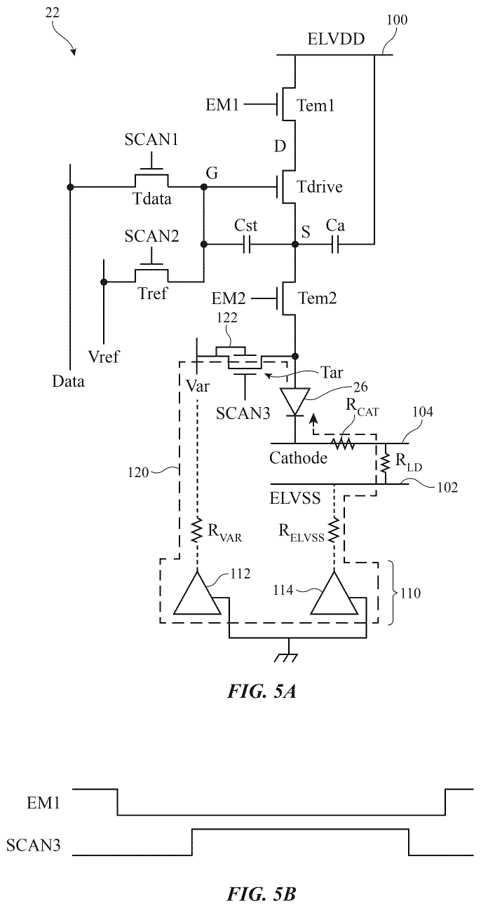

During the operations of block 402, the display circuitry can be configured in a vertical blanking period. Touch sensing operations can be performed during the vertical blanking period. In accordance with some embodiments, anode reset operations can also be performed during the vertical blanking period while the touch sensing operations are being performed (e.g., one or more anode reset transistors can be activated while the touch sensor circuitry is performing touch sensing operations). During the vertical blanking period, the diodes 26 in display pixels 22 do not emit light. This time during which the diodes 26 are inactive is thus sometimes referred to as an “inactive” emission or emission “off” period. Such operation might be employed for displays operating at higher refresh rates (e.g., refresh rates that are greater than 60 Hz, equal to or greater than 90 Hz, equal to or greater than 100 Hz, equal to or greater than 120 Hz, etc.). Performing anode reset operations while the touch sensing operations are being performed can, if care is not taken, inject display noise into the touch sensor circuitry. Such phenomenon can be illustrated in connection with FIG. 5A.

FIG. 5A is a circuit diagram showing one embodiment of an illustrative display pixel 22. As shown in FIG. 5A, display pixel 22 may include a light-emitting element such as an organic light-emitting diode 26, a capacitor such as storage capacitor Cst, an additional capacitor such as capacitor Ca, and thin-film transistors such a drive transistor Tdrive, a gate-voltage-setting transistor Tref, a data loading transistor Tdata, an anode reset transistor Tar, and emission transistors Tem1 and Tem2. Emission transistors Tem1 and Tem2 are sometimes referred to as emission control transistors. At least some or all of the transistors within pixel 22 can be implemented as semiconducting oxide transistors. “Semiconducting oxide” transistors can refer to and be defined herein as thin-film transistors having a channel region formed from semiconducting oxide material (e.g., indium gallium zinc oxide or IGZO, indium tin zinc oxide or ITZO, indium gallium tin zinc oxide or IGTZO, indium tin oxide or ITO, or other semiconducting oxide material) and are generally considered n-type (n-channel) transistors.

A semiconducting oxide transistor is notably different than a “silicon” transistor (e.g., a transistor having a polysilicon channel region deposited using a low temperature process sometimes referred to as LTPS or low-temperature polysilicon). Semiconducting oxide transistors exhibit lower leakage than silicon transistors, so implementing at least some of the transistors within pixel 22 can help reduce flicker (e.g., by preventing current from leaking away from the gate terminal of drive transistor Tdrive).

If desired, at least some of the transistors within pixel 22 may be implemented as silicon transistors such that pixel 22 has a hybrid configuration that includes a combination of semiconducting oxide transistors and silicon transistors (e.g., n-type LTPS transistors or p-type LTPS transistors). In yet other suitable embodiments, pixel 22 may include additional initialization transistors for apply an initialization or reference voltage to one or more internal nodes within pixel 22. As another example, display pixel 22 may further include additional switching or biasing transistors (e.g., one or more additional semiconducting oxide transistors or silicon transistors) for applying one or more bias voltages for improving the performance or operation of pixel 22.

In the example of FIG. 5A, thin-film transistors Tdrive, Tdata, Tref, Tar, Tem1, and Tem2 can all be implemented as n-type transistors (e.g., semiconducting oxide transistors and/or n-type silicon transistors). If desired, any of these transistors can alternatively be implemented as p-type (p-channel) silicon transistors. In general, n-type semiconducting oxide and silicon transistors are “active-high” devices (e.g., switches that are activated or turned on when the voltage at the gate terminals are driven high), whereas p-type silicon transistors are “active-low” devices (e.g., switches that are deactivated or turned off when the voltage at the gate terminals are driven low).

Drive transistor Tdrive has a gate terminal G, a drain terminal D, and a source terminal S. The terms “source” and “drain” are sometimes used interchangeably when referring to current-conducting terminals of a metal-oxide-semiconductor (MOS) transistor. The source and drain terminals are therefore sometimes referred to as “source-drain” terminals (e.g., a transistor has a gate terminal, a first source-drain terminal, and a second source-drain terminal). The term “activate” with respect to a switch (or transistor) may refer to or be defined herein as an action that places the switch in an “on” or low-impedance state such that the two terminals of the switch are electrically connected to conduct current. Activating a switch can sometimes be referred to as turning on or closing a switch. The term “deactivate” with respect to a switch (or transistor) may refer to or be defined herein as an action that places the switch in an “off” or high-impedance state such that the two terminals of the switch/transistor are electrically disconnected with minimal leakage current. Deactivating a switch can sometimes be referred to as turning off or opening a switch.

Transistor Tdrive, emission transistors Tem1 and Tem2, and light-emitting diode 26 are coupled in series between positive power supply line 100 (e.g., a power supply terminal on which positive power supply voltage ELVDD is provided) and ground power supply line 102 (e.g., a ground terminal on which ground power supply voltage ELVSS is provided). Positive power supply voltage ELVDD may be supplied to positive power supply terminal 100, whereas a ground power supply voltage ELVSS may be supplied to ground power supply terminal 102. Positive power supply voltage ELVDD may be 3 V, 4 V, 5 V, 6 V, 7 V, 2 to 8 V, greater than 6 V, greater than 8 V, greater than 10 V, greater than 12 V, 6-12 V, 12-20 V, or any suitable positive power supply voltage level. Ground power supply voltage ELVSS may be 0 V, −1 V, −2 V, −3 V, −4 V, −5 V, −6V, −7 V, less than 2 V, less than 1 V, less than 0 V, or any suitable ground or negative power supply voltage level.

Emission transistor Tem1 may have a gate terminal configured to receive first emission control signal EM1, whereas transistor Tem2 has a gate terminal configured to receive a second emission control signal EM2. This example in which emission transistors Tem1 and Tem2 receive different emission (control) signals is merely illustrative. In other embodiments, transistors Tem1 and Tem2 can receive the same emission control signal. During an emission phase (period), signals EM1 and EM2 can be asserted to turn on emission transistors Tem1 and Tem2, which allows current to flow from drive transistor Tdrive to diode 26. The degree to which drive transistor Tdrive is activated controls the amount of current flowing from terminal 100 to terminal 102 through diode 26 and therefore an amount of emitted light from display pixel 22.

In the example of FIG. 5A, storage capacitor Cst may be coupled between the gate and source terminals of drive transistor Tdrive. Data loading transistor Tdata may have a first source-drain terminal coupled to the gate terminal of transistor Tdrive, a second source-drain terminal coupled to a data line (e.g., a column line carrying the Data signal), and a gate terminal configured to receive a first scan control signal SCAN1. Transistor Tref may have a first source-drain terminal coupled to the gate terminal of transistor Tdrive, a second source-drain terminal coupled to a reference voltage Vref via a reference voltage line (e.g., a column line carrying reference voltage Vref), and a gate terminal configured to receive a second scan control signal SCAN2. Transistor Tref that is operable to pass reference voltage Vref onto the gate terminal of transistor Tdrive may therefore sometimes be referred to as a gate-voltage-setting transistor or a reference transistor. Voltage Vref may be a fixed voltage level that is equal to ELVDD, less than ELVDD, or some other voltage level between ELVSS and ELVDD.

Additional capacitor Ca may be coupled between the source terminal of transistor Tdrive and positive power supply line 100. This connection is illustrative. In other embodiments, capacitor Ca can be couped to ELVSS, Vref, Var, or other available/existing DC or static supply voltage within pixel 22. Device configurations in which capacitor Ca is shorted to the ELVDDEL line 100 is sometimes described herein as an example. Configured in this way, capacitor Ca can serve to boost the drive current levels of pixel 22 and is therefore sometimes referred to as a current boosting capacitor.

Anode reset transistor Tar may have a first source-drain terminal coupled to the anode terminal of diode 26 (sometimes referred to as the anode electrode), a second source-drain terminal configured to receive an anode reset voltage via an anode reset voltage line (e.g., a column line carrying anode reset voltage Var), and a gate terminal configured to receive a third scan control signal SCAN3. Diode 26 has a cathode terminal (sometimes referred to as the cathode electrode) coupled to the ELVSS ground power supply line 102 (sometimes referred to as a common power supply line).

The anode reset voltage Var can be driven by an associated anode reset voltage driver 112. The anode reset voltage line on which Var is provided can have an associated path resistance R_{VAR}. The ELVSS ground voltage can be driven by an associated ground voltage driver 114. The ground voltage line on which ELVSS is provided can have an associated ground path resistance R_{ELVSS}. Voltage drivers 112 and 114 can optionally be implemented as part of a power management circuit 110 separate from the array of pixels 22. In the example of FIG. 5A, the ELVSS ground power supply line 102 can be coupled to cathode terminal 104 of diode 26 through a conductive via structure (e.g., a laser drilling contact having an associated contact resistance R_{LD}). The cathode terminal 104 of one or more display pixels 22 can be implemented as a cathode layer that overlaps one or more pixels 22 and having an associated cathode resistance R_{CAT}.

In practice, the anode terminal of diode 26 can have an anode voltage that is dependent on the current brightness level of diode 26 (e.g., the anode voltage level is brightness or content dependent). For example, a higher gray level can lead to a higher anode voltage, whereas a lower gray level can lead to a lower anode voltage. During an anode reset operation, current can flow through anode reset transistor Tar and diode 26, as indicated by anode reset current path 120 (see dotted current path in FIG. 5A). The anode reset current path 120 can also sometimes be referred to herein as the anode “discharge” path. Depending on the voltage level present at the anode terminal of diode 26 at the beginning of the anode reset operation, the amount of current 120 flowing into the cathode terminal 104 can vary. The cathode can be electrically coupled to one or more touch sensor electrodes of the touch sensor circuitry. This can cause a varying amount of cathode rippling when an anode reset operation is performed during the vertical blanking period. Such image/content dependent cathode rippling can inadvertently be coupled to the touch sensor circuitry, resulting in undesired interference between the display and touch components.

The amount of cathode rippling at the cathode terminal (layer) 104 (see also cathode layer within layers 306 in FIG. 3) may be a function of the total resistance of the anode reset (discharge) current path 120. The total resistance of the discharge path 120 includes the on resistance of anode reset transistor Tar. Thus, in accordance with an embodiment, anode reset transistor Tar can have a back (bottom) gate terminal that is shorted to the anode reset voltage line, as shown by back gate connection 122. In a thin-film transistor stackup, the front gate terminal can be formed from a conductive layer above the active semiconducting oxide layer and is therefore sometimes referred to as the “top” gate conductor. On the other hand, the back gate terminal can be formed from a conductive layer below the active semiconductive oxide layer and is therefore sometimes referred to as the “bottom” or “back” gate conductor. Biasing transistor Tar in this way can increase the on resistance of transistor Tar (e.g., the resistance of transistor Tar when it is activated, sometimes referred to as the “on-state resistance”). Boosting the on resistance of transistor Tar in this way can be technically advantageous and beneficial to reduce the cathode rippling (e.g., to reduce the amount of voltage rippling seen at the cathode of diode 26), which can help mitigate the coupling of the display content dependent noise to the touch sensor circuitry.

FIG. 5B is a timing diagram showing illustrative signals for operating the display pixel shown in FIG. 5A during the vertical blanking period. As shown in FIG. 5B, signal EM1 can be pulsed low during the vertical blanking period. Driving signal EM1 low in this way deactivates transistor Tem1, which prevents emission current from flowing through diode 26. As a result, no light is emitted from pixel 22 during this time. The period during which signal EM1 is pulsed low is thus sometimes referred to as an emission “off” period. While signal EM1 is pulsed low, signal SCAN3 may be pulsed high to temporarily activate anode reset transistor Tar. The high pulse width of SCAN3 may be less than the low pulse width of EM1 (e.g., SCAN3 may be driven high sometime after the falling edge of EM1 and may be driven low before the next rising edge of EM1). The waveforms of FIG. 5B can thus be adopted to perform one or more anode reset operations during the vertical blanking period (e.g., although only one anode reset operation is shown in the example of FIG. 5B, multiple separate anode reset pulses can be employed while the touch sensor circuitry is activated, if desired).

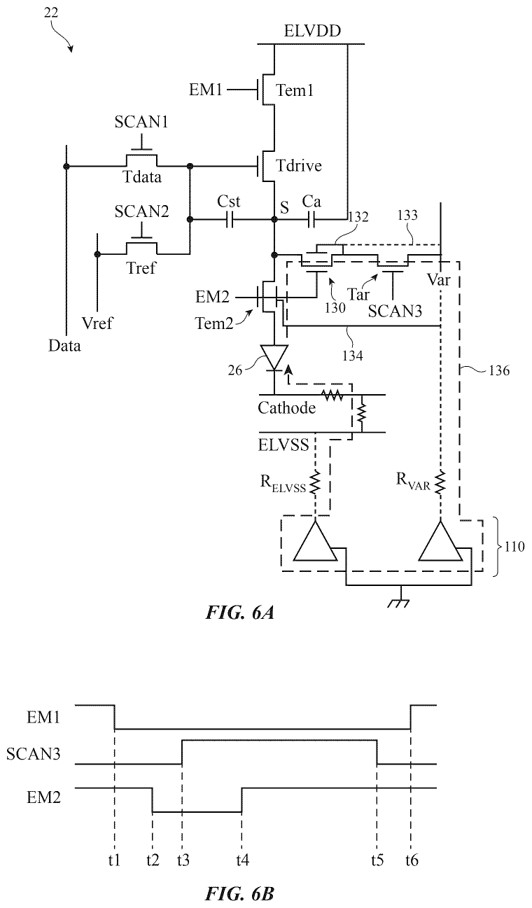

The embodiment of FIG. 5A in which anode reset transistor Tar is directly connected to the anode terminal of diode 26 is exemplary. FIG. 6A shows another embodiment of display pixel 22 in which anode reset transistor Tar is coupled to a node disposed between the drive transistor Tdrive and emission transistor Tem2. As shown in FIG. 6A, pixel 22 may further include an additional (second or secondary) anode reset transistor 130 coupled in series with anode reset transistor Tar, sometimes referred to herein as a “primary” anode reset transistor. In particular, primary anode reset transistor Tar may have a first source-drain terminal coupled to the anode reset voltage line, a second source-drain terminal coupled to transistor 130, and a gate terminal configured to receive signal SCAN3. Secondary (or auxiliary) anode reset transistor 130 may have a first source-drain terminal coupled to transistor Tar, a second source-drain terminal coupled to the node between transistors Tdrive and Tem2, a front (top) gate terminal configured to receive emission control signal EM2, and a back (bottom) gate terminal coupled to its first source-drain terminal, as shown by back gate connection 132. If desired, the back gate terminal of transistor 130 can alternatively be coupled to the anode reset voltage line, as indicated by dotted connection 133. Transistor Tem2 can also be provided with a back (bottom) gate terminal that is coupled to the anode reset voltage line, as indicated by back gate connection 134. The remainder of pixel 22 is identical to that already described in connection with FIG. 5A and need not be reiterated to avoid obscuring the present embodiment.

Configured in this way, pixel 22 can exhibit an anode reset (discharge) current path 136 that flows through at least transistors Tar, 130, and Tem2 during an anode reset operation. In comparison to the embodiment of FIG. 5A having only one pixel transistor Tar in the discharge current path, the embodiment of FIG. 6A having three pixel transistors Tar, 130, and Tem2 in the discharge current path 136 can help further increase the total resistance of path 136. Maximizing the on resistance of current path 136 in this way can be technically advantageous and beneficial to reduce the cathode rippling (e.g., to reduce the amount of voltage rippling seen at the cathode of diode 26), which can help mitigate the interference of the display content dependent noise to the touch sensor operation.

FIG. 6B is a timing diagram showing illustrative signals for operating the display pixel shown in FIG. 6A during the vertical blanking period. As shown in FIG. 6B, signal EM1 can be pulsed low during the vertical blanking period. Driving signal EM1 low in this way deactivates transistor Tem1, which prevents emission current from flowing through diode 26. As a result, no light is emitted from pixel 22 during this time. The period during which signal EM1 is pulsed low is thus sometimes referred to as an emission “off” period. While signal EM1 is pulsed low, signal SCAN3 may be pulsed high to temporarily activate anode reset transistor Tar. The high pulse width of SCAN3 may be less than the low pulse width of EM1 (e.g., SCAN3 may be driven high at time t3 subsequent to the falling edge of EM1 at time t1 and may be driven low at time t5 before the next rising edge of EM1 at time t6). Moreover, signal EM2 should be taken high prior to time t1, driven low at time t2 (e.g., between t1 and t3), and driven high at time t4 (e.g., between t3 and t5). Operated in this way, transistors Tem2 and 130 can first be temporarily activated (e.g., at least between times t1 and t2) while transistor Tar is later activated at time t3. Transistors Tem2 and 130 can again be reactivated at time t4. Staggering the activation times of transistors Tem2, 130, and Tar along the anode reset discharge current path 136 in this way can be technically advantageous and beneficial to reduce a peak of the discharge current by 50%, which can help reduce cathode rippling.

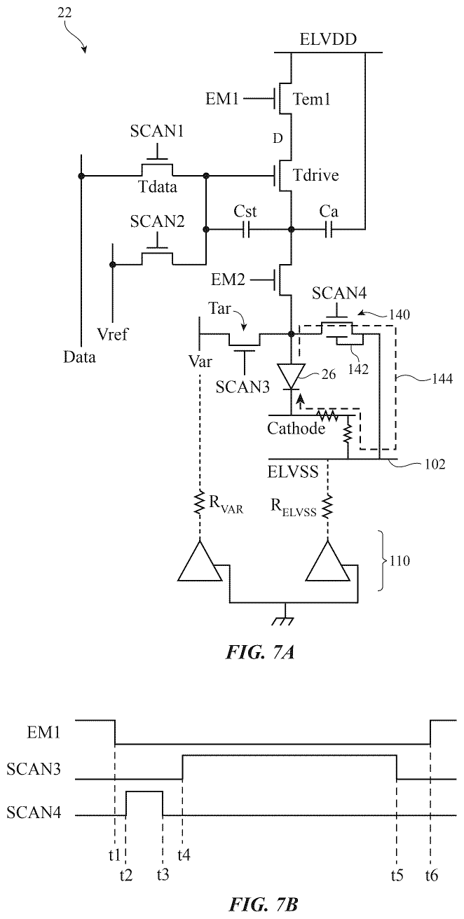

The embodiment of FIG. 5A in which pixel 22 includes only one anode reset transistor Tar coupled to the anode terminal of diode 26 is exemplary. FIG. 7A shows another embodiment of pixel 22 that includes an additional (secondary or auxiliary) anode reset transistor 140. As shown in FIG. 7A, the secondary anode reset transistor 140 can have a first source-drain terminal coupled to the anode terminal of diode 26, a second source-drain terminal coupled to the EVLSS ground line 102, a front (top) gate terminal configured to receive scan control signal SCAN4, and a back (bottom) gate terminal coupled to its second source-drain terminal, as shown by back gate connection 142. Thus, when only transistor 140 is activated, pixel 22 can exhibit an anode reset (discharge) current path 144 that flows through transistor 140 and diode 26. In comparison to the embodiment of FIG. 5A where the discharge current path 120 includes resistances R_{VAR} and R_{ELVSS}, the discharge current path 144 of FIG. 7A circumvents resistances R_{VAR} and R_{ELVSS}. Since voltage is a produce of resistance and current, eliminating resistances R_{VAR} and R_{ELVSS} from the discharge current path can be technically advantageous and beneficial by reducing the cathode voltage rippling. The remainder of pixel 22 of FIG. 7A is identical to that already described in connection with FIG. 5A and need not be reiterated to avoid obscuring the present embodiment.

FIG. 7B is a timing diagram showing illustrative signals for operating the display pixel shown in FIG. 7A during the vertical blanking period. As shown in FIG. 7B, signal EM1 can be pulsed low during the vertical blanking period. Driving signal EM1 low in this way deactivates transistor Tem1, which prevents emission current from flowing through diode 26. As a result, no light is emitted from pixel 22 during this time. The period during which signal EM1 is pulsed low is thus sometimes referred to as an emission “off” period. While signal EM1 is pulsed low, signal SCAN3 may be pulsed high to temporarily activate anode reset transistor Tar. The high pulse width of SCAN3 may be less than the low pulse width of EM1 (e.g., SCAN3 may be driven high at time t4 subsequent to the falling edge of EM1 at time t1 and may be driven low at time t5 before the next rising edge of EM1 at time t6).

Moreover, signal SCAN4 should be pulsed high between times t1 and t4 (e.g., SCAN4 should be driven high after time t1 and driven low before time t4). Operated in this way, transistor 140 is temporarily activated to reset the anode terminal via discharge path 144 shown in FIG. 7A (e.g., to first eliminate any brightness or content dependent voltage at the anode). Later (at time t4), the primary anode reset transistor Tar can then be activated to completely reset the anode terminal. Staggering the activation times of transistors 140 and Tar in this way can be technically advantageous and beneficial to erase any content dependent anode reset voltage using transistor 140 prior to the main anode reset operation via transistor Tar, which can help reduce cathode rippling and can mitigate the interference of the display content dependent noise to the touch sensor operation.

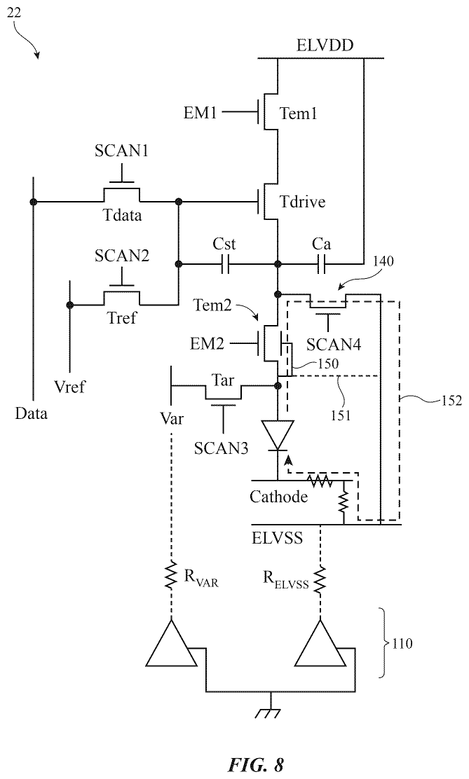

The embodiment of FIG. 7A in which both primary anode reset transistor Tar and secondary anode reset transistor 140 are directly coupled to the anode terminal of diode 26 is exemplary. FIG. 8 shows another embodiment of pixel 22 in which the primary anode reset transistor Tar is directly coupled to the anode terminal of diode 26 and the secondary anode reset transistor 140 is coupled to a node disposed between transistors Tdrive and Tem2. As shown in FIG. 8, the secondary anode reset transistor 140 can have a first source-drain terminal coupled to the node between transistors Tdrive and Tem2 (e.g., to the source terminal of Tdrive), a second source-drain terminal coupled to the EVLSS ground line 102, and a gate terminal configured to receive scan control signal SCAN4. Transistor Tem2 may have a back (bottom) gate terminal coupled to the anode terminal, as shown by back gate connection 150. The back gate terminal of transistor Tem2 can alternatively be coupled to the ELVSS line, as illustrated by dotted connection 151.

Configured in this way, when only transistor 140 is activated, pixel 22 can exhibit an anode reset (discharge) current path 152 that flows through transistor 140, transistor Tem2, and diode 26. In comparison to the embodiment of FIG. 5A where the discharge current path 120 includes resistances R_{VAR} and R_{ELVSS}, the discharge current path 152 of FIG. 8 circumvents resistances R_{VAR} and R_{ELVSS}, which can be technically advantageous and beneficial to reduce the cathode voltage rippling. The remainder of pixel 22 of FIG. 8 is identical to that already described in connection with FIG. 5A and need not be reiterated to avoid obscuring the present embodiment. The operation of pixel 22 shown in FIG. 8 can be identical to that already described in connection with FIG. 7B and need not be reiterated to avoid obscuring the present embodiment.

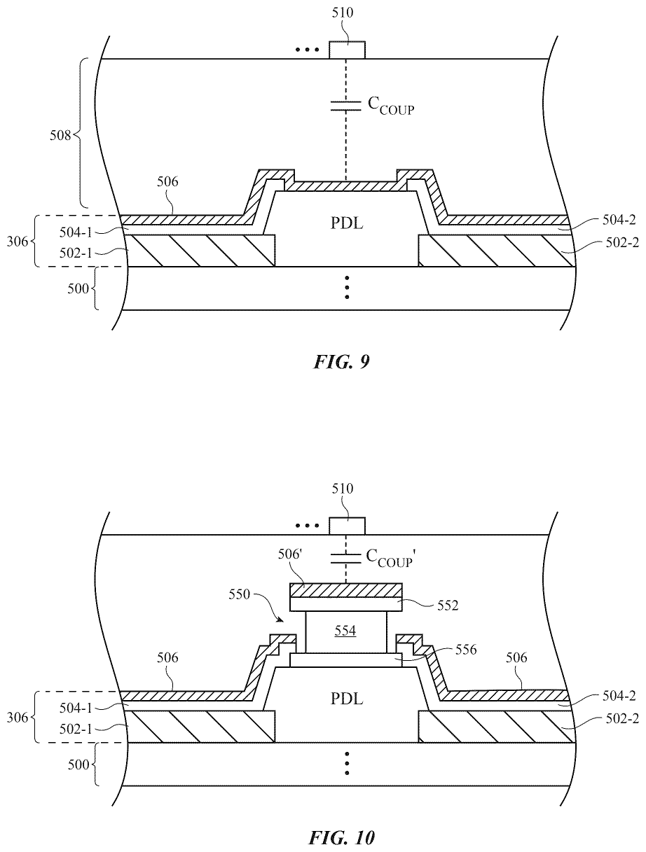

In accordance with some embodiments, the amount of interference between the display circuitry and the touch sensor circuitry can further depend on an amount of capacitance between a conductive structure of the touch sensor circuitry and the conductive cathode layer. FIG. 9 is a side view of a continuous cathode layer 506 formed over a pixel definition structure in some portions of the display. As shown in FIG. 9, layers 500 may represent thin-film layers in which one or more thin-film transistors and thin-film capacitors are formed. An anode layer including anode conductors 502-1 and 502-2 can be formed on thin-film layers 500. Anode conductor 502-1 may serve as the anode terminal for a first display pixel, whereas anode conductor 502-2 may serve as the anode terminal for a second display pixel adjacent to the first display pixel. Adjacent pixels can be separated by a pixel isolation structure such as a pixel definition structure PDL. The pixel definition structure can be formed along a peripheral edge or border of each display pixel 22.

A cathode layer such as cathode layer 506 may be formed over the pixel definition structure. First emissive material 504-1 may be formed between cathode layer 506 and the first anode conductor 502-1, whereas second emissive material 504-2 may be formed between cathode layer 506 and the second anode conductor 502-2. The first emissive material 504-1 can be configured to emit light of a first color, whereas the second emissive material 504-2 can be configured to emit light of a second color different than the first color. The emissive material can be employed, in the presence of applied electric field, to emit red light, blue light, green light, clear (white) light, and/or other colors of light. Layers 502, 504, and 506 form respective organic light-emitting diodes 26 and are therefore sometimes referred to as organic light-emitting diode (OLED) layers. Layers 502, 504, and 506 of FIG. 9 may represent the OLED layers 306 described in connection with FIG. 3, where cathode layer 506 is the topmost layer within OLED layers 306.

Encapsulation layers 508 can be formed on top of cathode layer 506. In general, encapsulation layers 508 may include one or more inorganic encapsulation layers and one or more organic encapsulation layers. As an example, layers 508 can include a first inorganic encapsulation layer, an organic encapsulation layer formed on the first inorganic encapsulation layer, and a second inorganic encapsulation layer formed on the organic encapsulation layer. Encapsulation layers 508 formed in this way can help prevent moisture and other potential contaminants from damaging the conductive circuitry covered by layers 508.

As shown in FIG. 9, one or more touch sensor electrodes such as touch sensor electrode 510 can be formed or above encapsulation layers 508. The amount of interference between the display circuitry and the touch sensor circuitry can depend on a coupling capacitance Ccoup between touch sensor electrode 510 and the cathode layer 506. Thus, in accordance with some embodiments, one or more portions of the display stackup can include additional support structures configured to elevate selected portions of the cathode layer (see, e.g., FIG. 10).

As shown in the side view of FIG. 10, certain portions of the display might include structures 550 formed on the pixel definition structure PDL. Structures 550 can include a first layer 556, a second layer 554, and a third layer 552. As an example, the first and third layers can each be formed from silicon oxide while the second layer is formed from silicon nitride. As another example, the first layer 556 can be silicon oxide, the second layer 554 can be silicon nitride, and the third layer 552 can be indium gallium zinc oxide (IGZO, a semiconducting material). As another example, the first layer 556 can be silicon oxide, the second layer 554 can be silicon nitride, and the third layer 552 can include both indium gallium zinc oxide (IGZO) and silicon oxide sublayers. These examples are illustrative. In general, each of layers 552, 554, and 556 can include one or more dielectric layers and/or one or more semiconductor (semiconducting) layers. The first layer 556 can have a first width. The third layer 552 can have a third width. The second interposing layer 554 can have a second width that is smaller than the first width and also smaller than the third width.

Configured in this way, a portion of the cathode layer such as cathode layer portion 506′ formed on the upper surface of layer 552 can be elevated with respect to the surrounding cathode layer 506. Although cathode layer 506 and cathode layer portions 506′ are formed at the same time (e.g., via the same thin-film processing step during fabrication) and thus from the same conductive material, cathode layer portion 506′ will be raised directly over the pixel definition structures by support structures 550. As a result, the elevated cathode portion 506′ is physically and electrically disconnected from the surrounding cathode layer 506 (e.g., cathode portion 506′ is electrically floating). Thus, support structures 550 for elevating the electrically floating/isolated cathode portion 506′ are sometimes referred to and defined herein as “floating cathode support structures.” Electrically isolating cathode portion 506′ in this way can reduce the capacitive coupling Ccoup′ between the touch sensor electrode 510 and the floating cathode portion 506′. Reducing Ccoup′ can be technically advantageous and beneficial to reduce the amount of noise interference between the display circuitry and the touch sensor circuitry

FIG. 11 is a top (layout/plan) view of a display pixel 22 having at least three subpixels in accordance with some embodiments. As shown in FIG. 11, pixel 22 can include a first subpixel 600-1, a second subpixel 600-2, and a third subpixel 600-3. The first subpixel 600-1 can be configured to emit light of a first color; the second subpixel 600-2 can be configured to emit light of a second color different than the first color; and the third subpixel 600-3 can be configured to emit light of a third color different than the first and second colors. As an example, subpixel 600-1 may represent a red subpixel; subpixel 600-2 may represent a green subpixel; and subpixel 600-3 may represent a blue subpixel. Such subpixel arrangement is merely illustrative. The various subpixels 600 can be surrounded by pixel definition (PDL) structures 510. The pixel definition structures 510 can form borders or edges around each subpixel region and can be configured to provide electrical and physical isolation between adjacent subpixel regions 600 and adjacent pixels 22. In other words, the pixel definition structures can be formed along a periphery of the various display pixel regions.

In accordance with some embodiments, floating cathode support can be formed on one or more portions of the pixel definition structures 510. In the example of FIG. 11, multiple discrete floating cathode support structures (e.g., structures 550 shown and described in connection with FIG. 10) can be formed on portions 602 of the pixel definition structures 510. Configured in this way, portions of the cathode layer within the dotted portions 602 of FIG. 11 will be elevated with respect to the surrounding cathode layer and thus be electrically floating, whereas portions of the cathode layer outside the dotted portions 602 will be electrically coupled or driven to the ELVSS ground voltage. For example, FIG. 10 is the side view taken along cross section AA′ traversing a floating cathode layer portion. On the other hand, FIG. 9 is the side view taken along cross section BB′ traversing a portion of the display without any floating cathode support structures.

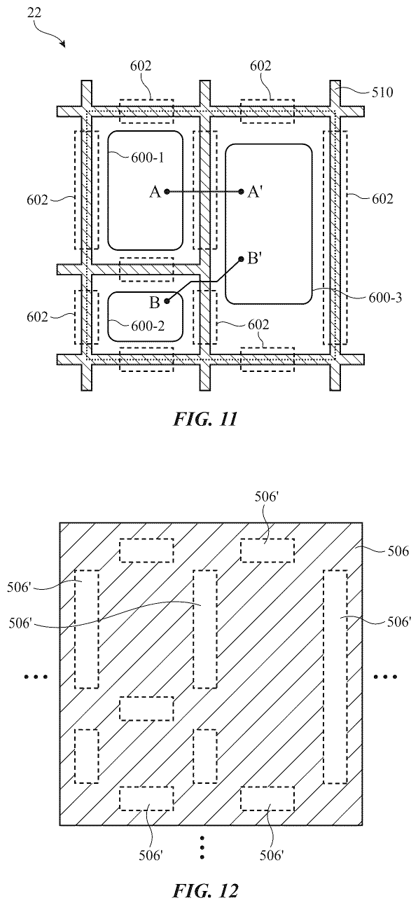

FIG. 12 is a top (layout/plan) view of cathode layer 506 in the display pixel of FIG. 11. As shown in FIG. 12, the shaded portion of cathode layer 506 will be electrically coupled or driven to the ELVSS ground voltage, whereas the unshaded dotted regions 506′ correspond to the dotted portions 602 of FIG. 11 and thus represent electrically floating cathode portions 506′(see also FIG. 10). A large portion of the cathode layer 506 overlaps with the various display pixel regions. Providing electrically floating cathode portions 506′ along the pixel definition structures in this way can reduce the capacitive coupling between the touch sensor electrodes and the display cathode layer, which can be technically advantageous and beneficial to reduce the amount of noise interference between the display circuitry and the touch sensor circuitry

As described above in connection with FIGS. 4-8, during an anode reset operation, a discharge current can flow through the cathode terminal the diode 26. Since the cathode layer can be capacitively coupled to the touch sensor electrodes, as described above in connection with FIGS. 9-12, reducing the current spike of such discharge current during the anode reset operation can help reduce the cathode voltage rippling, which will reduce the amount of noise interference between the display circuitry and the touch sensor circuitry.

Consider a scenario in which a gate driver formed on one side of the pixel array is configured to output a scan signal SCAN3 that is simultaneously fed to at least two different rows in the pixel array. As described in connection with FIGS. 4-8, scan signal SCAN3 can be used to activate the anode reset transistors Tar in a row of pixels 22. Simultaneously activating the anode reset transistors in two different pixel rows might be suboptimal since discharging two rows of pixels at the same time might lead to a large amount of cathode voltage rippling.

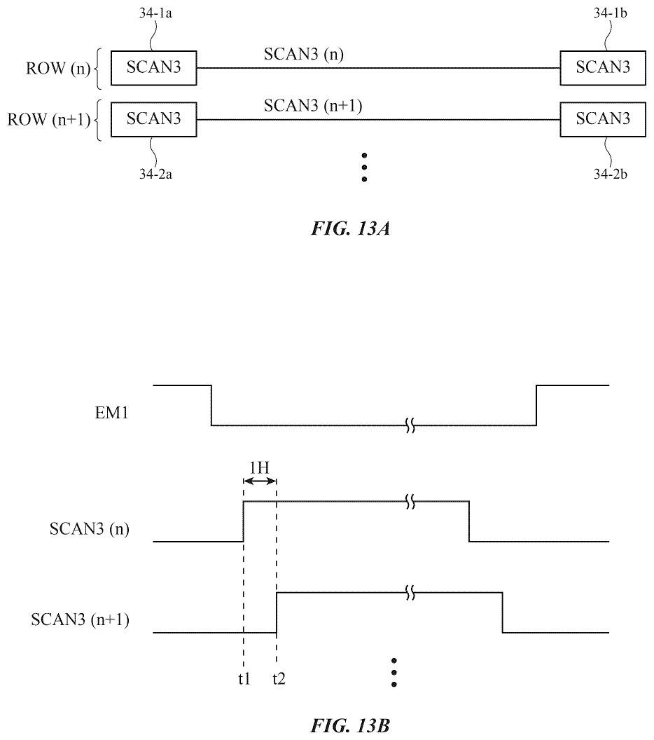

FIGS. 13A and 13B illustrate an embodiment of a gate driving scheme that splits up the timing of SCAN3 into two separate moments. As shown in FIG. 13A, a first row of pixels—Row(n)—may be driven by a first SCAN3 gate driver 34-1a disposed on a left peripheral edge of the pixel array and by a second SCAN3 gate driver 34-1b disposed on a right peripheral edge of the pixel array. Similarly, a second row of pixels—Row(n+1)—may be driven by a third SCAN3 gate driver 34-2a disposed on the left peripheral edge of the pixel array and by a fourth SCAN3 gate driver 34-2b disposed on the right peripheral edge of the pixel array. These peripheral gate drivers may be part of a chain of gate driver circuits within gate driver circuitry 34 of FIG. 2. Gate drivers 34-1a and 34-1b can be configured to output a corresponding signal SCAN3(n) for controlling the anode reset transistors along Row(n). Similarly, gate drivers 34-2a and 34-2b can be configured to output a corresponding signal SCAN3(n+1) for controlling the anode reset transistors along Row(n+1). Such SCAN3 driving scheme in which each row of pixels is driven by separate gate drivers from both sides is sometimes referred to as a per-row or single-row head-to-head anode reset driving scheme.

FIG. 13B is a timing diagram for operating the gate driving scheme of FIG. 13A. As shown in FIG. 13B, signal SCAN3(n) can be pulsed at a first time t1, whereas signal SCAN3(n+1) can be pulsed at a second time t2. The rising edge of the two SCAN3 pulses can be offset in time by a single row time (1H) (e.g., the SCAN3(n+1) pulse can be delayed with respect to the SCAN3(n) signal by 1H). A single “row time” (1H) can refer to an amount of time it takes to address or scan a single row of displays in the display. Splitting up or staggering the SCAN3 pulses for two rows that would otherwise be simultaneously asserted can help reduce the discharge current spike by 50%, which will substantially mitigate any cathode voltage rippling. In general, each staggered SCAN3 pulse can be longer than the 1H period (e.g., with a pulse width longer than 50% of the emission off period (e.g., the period when EM1 is low), longer than 60% of the emission off period, longer than 70% of the emission off period, longer than 80% of the emission off period, or longer than 90% of the emission off period).

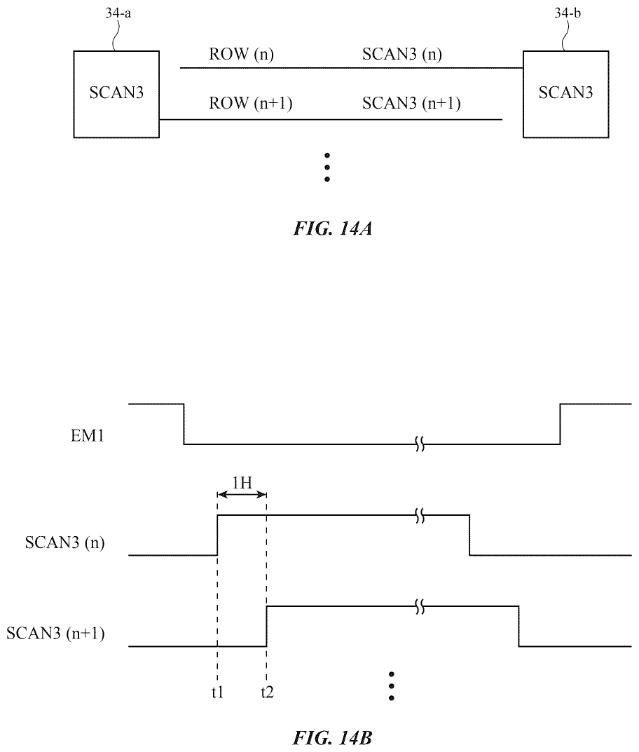

The per-row head-to-head anode reset driving scheme of FIG. 13A is exemplary. FIG. 14A shows another embodiment where each row is only driven by one peripheral gate driver. As shown in FIG. 14A, a first row of pixels—Row(n)—may be driven by a first SCAN3 gate driver 34-b disposed on a right peripheral edge of the pixel array, whereas a second row of pixels—Row(n+1)—may be driven by a second SCAN3 gate driver 34-a disposed on a left peripheral edge of the pixel array. These peripheral gate drivers may be part of a chain of gate driver circuits within gate driver circuitry 34 of FIG. 2. Gate driver 34-b can be configured to output a corresponding signal SCAN3(n) for controlling the anode reset transistors along Row(n). Similarly, gate drivers 34-a can be configured to output a corresponding signal SCAN3(n+1) for controlling the anode reset transistors along Row(n+1). Such SCAN3 driving scheme in which each row of pixels is driven by a gate driver from only one edge is sometimes referred to as a per-row or single-row single-ended (interlaced) anode reset driving scheme.

FIG. 14B is a timing diagram for operating the gate driving scheme of FIG. 14A. As shown in FIG. 14B, signal SCAN3(n) can be pulsed at a first time t1, whereas signal SCAN3(n+1) can be pulsed at a second time t2. The rising edge of the two SCAN3 pulses can be offset in time by a single row time (1H) (e.g., the SCAN (n+1) pulse can be delayed with respect to the SCAN3(n) signal by 1H). Splitting up or staggering the SCAN3 pulses for two rows that would otherwise be simultaneously asserted can help reduce the discharge current spike by 50%, which will substantially mitigate any cathode voltage rippling. In general, each staggered SCAN3 pulse can be longer than the 1H period (e.g., with a pulse width longer than 50% of the emission off period (e.g., the period when EM1 is low), longer than 60% of the emission off period, longer than 70% of the emission off period, longer than 80% of the emission off period, or longer than 90% of the emission off period).

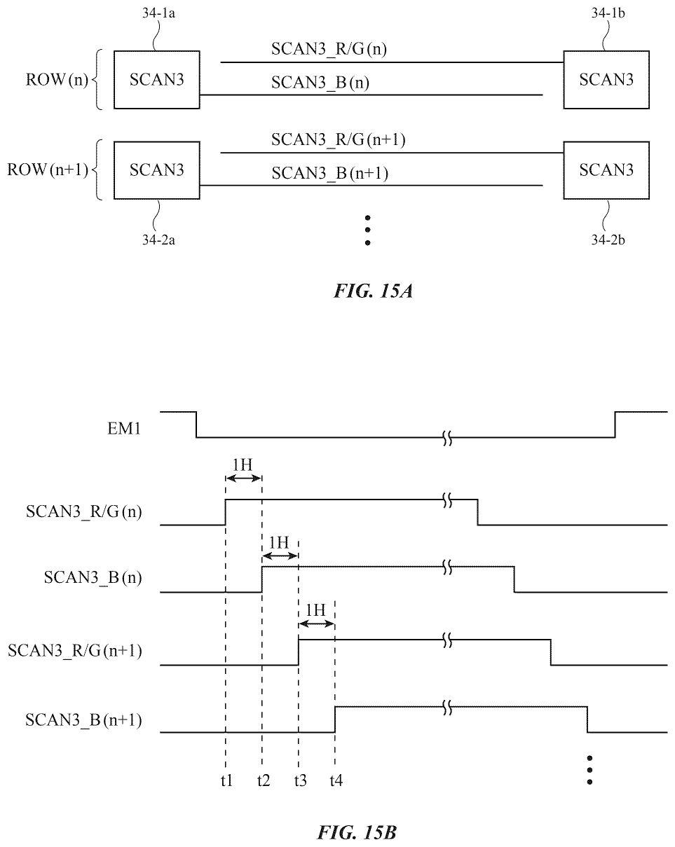

The gate driving schemes of FIGS. 13-14 assume that SCAN3(n) and SCAN3(n+1) are being fed to all of the subpixels within each pixel 22. FIG. 15A shows another embodiment in which the SCAN3 signals for different subpixels are split up in time. As shown in FIG. 15A, a first gate driver 34-1a disposed on the left edge of the array can be configured to output signal SCAN3_B(n) to all of the blue subpixels along Row(n), whereas a second gate driver 34-1b disposed on the right edge of the array can be configured to output signal SCAN3_R/G(n) to all of the red and green subpixels along Row(n). Similarly, a third gate driver 34-2a disposed on the left edge of the array can be configured to output signal SCAN3_B(n+1) to all of the blue subpixels along Row(n+1), whereas a fourth gate driver 34-2b disposed on the right edge of the array can be configured to output signal SCAN3_R/G(n+1) to all of the red and green subpixels along Row(n+1). These peripheral gate drivers may be part of a chain of gate driver circuits within gate driver circuitry 34 of FIG. 2.

FIG. 15B is a timing diagram for operating the gate driving scheme of FIG. 15A. As shown in FIG. 15B, signal SCAN3_R/G(n) can be pulsed at a first time t1; signal SCAN3_B(n) can be pulsed at a second time t2; signal SCAN3_R/G(n+1) can be pulsed at a third time t3; and signal SCAN3_B(n+1) can be pulsed at a fourth time t4. These four SCAN3 pulses can be successively staggered in time by a single row time (1H). Splitting up or staggering the SCAN3 pulses for two rows (and different colors) that would otherwise be simultaneously asserted can help reduce the discharge current spike by 50% or more, which will substantially mitigate any cathode voltage rippling. In general, other gate driving schemes for mitigating cathode voltage rippling or reducing the discharge current spike during an anode reset operation can be additionally or alternatively be employed. In general, each staggered SCAN3 pulse can be longer than the 1H period (e.g., with a pulse width longer than 50% of the emission off period, longer than 60% of the emission off period (e.g., the period when EM1 is low), longer than 70% of the emission off period, longer than 80% of the emission off period, or longer than 90% of the emission off period).

The foregoing is merely illustrative and various modifications can be made to the described embodiments. The foregoing embodiments may be implemented individually or in any combination.

What is claimed is:

1. Circuitry comprising:
a light-emitting diode;
a drive transistor coupled in series with the light-emitting diode;
a storage capacitor coupled to a gate terminal of the drive transistor; and
an anode reset transistor configured to reset an anode of the light-emitting diode and coupled to an anode reset voltage line, wherein the light-emitting diode comprises a cathode that is electrically coupled to one or more touch sensor electrodes, and wherein the anode reset transistor is activated while the touch sensor electrodes are performing touch sensing operations.

2. The circuitry of claim 1, wherein the anode reset transistor comprises a front gate terminal configured to receive a signal control signal and a back gate terminal coupled to the anode reset voltage line for increasing an on-state resistance of the anode reset transistor.

3. The circuitry of claim 2, wherein the anode reset transistor is directly coupled to the anode of the light-emitting diode.

4. The circuitry of claim 2, further comprising:
an emission transistor coupled in series with the drive transistor, wherein the emission transistor is deactivated during a vertical blanking period and wherein the anode reset transistor is activated for a portion of time during which the emission transistor is deactivated.

5. The circuitry of claim 1, further comprising:
an emission transistor having a first source-drain terminal coupled to the anode, a second source-drain terminal coupled to the anode reset transistor, and a gate terminal configured to receive an emission signal; and
an additional transistor having a first source-drain terminal coupled to the emission transistor, a second source-drain terminal coupled to the anode reset transistor, and a gate terminal configured to receive the emission signal.

6. The circuitry of claim 5, wherein the emission transistor comprises a back gate terminal coupled to the anode reset voltage line, and wherein the additional transistor comprises a back gate terminal coupled to its second source-drain terminal or the anode reset voltage line.

7. The circuitry of claim 5, further comprising:
an additional emission transistor coupled in series with the drive transistor, wherein the additional emission transistor is deactivated during a vertical blanking period, wherein the anode reset transistor is activated for a portion of time during which the emission transistor is deactivated, and wherein the emission transistor is deactivated while the additional emission transistor is deactivated during the vertical blanking period and is activated during the portion of time when the anode reset transistor is activated.

8. The circuitry of claim 1, further comprising:
an emission transistor having a first source-drain terminal coupled to the anode and the anode reset transistor, a second source-drain terminal coupled to the drive transistor, and a gate terminal configured to receive an emission signal; and
an additional transistor having a first source-drain terminal coupled to the anode and having a second source-drain terminal coupled to a ground line.

9. The circuitry of claim 8, wherein the additional transistor comprises a back gate terminal coupled to the ground line.

10. The circuitry of claim 8, further comprising:
an additional emission transistor coupled in series with the drive transistor, wherein the additional emission transistor is deactivated during a vertical blanking period, wherein the additional transistor is activated for a first portion of time during which the additional emission transistor is deactivated during the vertical blanking period, and wherein the anode reset transistor is activated for a second portion of time, after than the first portion of time, during which the additional emission transistor is deactivated during the vertical blanking period.

11. The circuitry of claim 1, further comprising:
an emission transistor having a first source-drain terminal coupled to the anode and the anode reset transistor, a second source-drain terminal coupled to the drive transistor, and a gate terminal configured to receive an emission signal; and
an additional transistor having a first source-drain terminal coupled to a node disposed between the emission transistor and the drive transistor and having a second source-drain terminal coupled to a ground line.

12. The circuitry of claim 11, wherein the emission transistor comprises a back gate terminal coupled to the anode or the ground line.

13. The circuitry of claim 11, further comprising:
an additional emission transistor coupled in series with the drive transistor, wherein the additional emission transistor is deactivated during a vertical blanking period, wherein the additional transistor is activated for a first portion of time during which the additional emission transistor is deactivated during the vertical blanking period, and wherein the anode reset transistor is activated for a second portion of time, after the first portion of time, during which the additional emission transistor is deactivated during the vertical blanking period.

14. The circuitry of claim 1, further comprising:
a first emission transistor coupled between a power supply line and the drive transistor;
a second emission transistor coupled between the drive transistor and the light-emitting diode;
an additional capacitor coupled having a first terminal coupled to the power supply line and having a second terminal coupled to a node between the drive transistor and the second emission transistor;
a data loading transistor coupled between a data line and the gate terminal of the drive transistor; and
a gate-voltage-setting transistor coupled between a reference voltage line and the gate terminal of the drive transistor.

15. Circuitry comprising:
a plurality of display pixel regions;
pixel definition structures formed along a periphery of the plurality of display pixel regions;
a cathode layer overlapping with the plurality of display pixel regions;
cathode layer portions disconnected from the cathode layer and formed directly over portions of the pixel definition structures; and
one or more touch sensor electrodes disposed over the cathode layer portions.

16. The circuitry of claim 15, wherein the cathode layer is electrically coupled to a ground power supply voltage, and wherein the cathode layer portions are electrically floating.

17. The circuitry of claim 15, further comprising:
floating cathode support structures formed between the pixel definition structures and the cathode layer portions.

18. The circuitry of claim 17, wherein the floating cathode support structures comprises:
a first layer of dielectric material;
a second layer of dielectric material formed on the first layer of dielectric material; and
a third layer including one or more of dielectric material and semiconducting material formed on the second layer of dielectric material.

19. The circuitry of claim 18, wherein the first layer comprises a first width, the third layer comprises a third width, and the second layer comprises a second width that is smaller than the first width and smaller than the third width.

20. The circuitry of claim 15, further comprising:
encapsulation layers disposed between the cathode layer and the one or more touch sensor electrodes, the encapsulation layers comprising at least one organic layer interposed between inorganic layers.

21. A method of operating a touch screen display, comprising:
outputting a first scan pulse to a first row of display pixels, wherein the first scan pulse is configured to activate a plurality of anode reset transistors in the first row of display pixels;
after outputting the first scan pulse, outputting a second scan pulse to a second row of display pixels, wherein the second scan pulse is configured to activate a plurality of anode reset transistors in the second row of display pixels; and
performing touch sensing operations while outputting the first and second scan pulses.

22. The method of claim 21, wherein the first scan pulse and the second scan pulse are offset by at least one row time of the touch screen display, and wherein the first and second can pulses each have a pulse width that is greater than 50% of an emission off period.

23. The method of claim 21, further comprising:
with a first gate driver disposed along a first edge of the touch screen display, outputting the first scan pulse;
with a second gate driver disposed along a second edge, opposing the first edge, of the touch screen display, outputting the first scan pulse;
with a third gate driver disposed along the first edge of the touch screen display, outputting the second scan pulse; and
with a fourth gate driver disposed along the second edge of the touch screen display, outputting the second scan pulse.

24. The method of claim 21, further comprising:
with only a first gate driver disposed along a first edge of the touch screen display, outputting the first scan pulse; and
with only a second gate driver disposed along a second edge, opposing the first edge, of the touch screen display, outputting the second scan pulse.

25. The method of claim 21, further comprising:
after outputting the first scan pulse and before outputting the second scan pulse, outputting a third scan pulse to the first row of display pixels; and
after outputting the second scan pulse, outputting a fourth scan pulse to the second row of display pixels, wherein:
the first scan pulse is conveyed to a plurality of anode reset transistors within red and green subpixels in the first row of display pixels;
the third scan pulse is conveyed to a plurality of anode reset transistors within blue subpixels in the second row of display pixels;
the second scan pulse is conveyed to a plurality of anode reset transistors within red and green subpixels in the second row of display pixels; and
the fourth scan pulse is conveyed to a plurality of anode reset transistors within blue subpixels in the second row of display pixels.
